(19) United States
(12) Patent Application Publication
(10) Pub. No.: US 2022/0177163 A1
(43) Pub. Date: Jun. 9, 2022

(54) Aircraft Line Replacement Unit Testing Device and Method To Use

(71) Applicant: John Bloomfield, Palm Coast, FL (US)

(72) Inventor: John Bloomfield, Palm Coast, FL (US)

(21) Appl. No.: 17/112,149

(22) Filed: Dec. 4, 2020

(51) Int. Cl. B64F 5/60; G01R 31/58

(52) U.S. Cl. CPC B64F 5/60; G01R 31/58

(57) ABSTRACT

The testing of aircraft systems is required on a periodic basis according to Government regulations or when error messages occur. The application allows the technician to test the integrity of line replacement unit without the need to remove adjacent line replacement units. The technician will focus the scope of maintenance activities on the suspect system without the need to remove adjacent line replacement units.

### BACKGROUND OF THE INVENTION

### A. Field of the Invention

This device will allow the testing of the aircraft wiring interface to a line replacement unit that is used aboard an aircraft. The line replacement unit contains electronics that control a specific function of an aircraft. In this case the application will discuss a landing gear control unit (LGCU), which is a line replacement unit that specifically controls the operation of the landing gear. Although the application discusses the LGCU the principles involved with this type of unit would be applicable to other line replacement units.

In any aircraft there are electronic components that control the operation of various onboard systems. These systems include landing gear, avionics, and navigation systems to name just a few. Each of these systems are vital to the safe operation of the aircraft and all aircraft have these systems. The testing of these systems involve the use of electronic testing equipment that is used to test the integrity of the circuits that control the various systems. The application makes the testing of the interface for the line replacement units much simpler for the technician; the accuracy of the testing results is not compromised by this application.

### B. Prior Art

There are other prior art references that discuss the testing of line replacement units and the importance of testing a line replacement unit. A representative example of this type of device in the prior art can be found at Szeto U.S. Patent Number which is an aircraft LRU data collection and reliability prediction device; this is not a testing device that is described in the current application. The Szeto reference does highlight the need to test LRUs whereas this application only tests the circuit interface.

None of the prior art teaches a device and method to test that is contemplated by this device.

### BRIEF SUMMARY OF THE INVENTION

A line replacement unit (LRU) is a structure that houses electronics that control the operation of different systems in an aircraft. The LRU is a standard piece of equipment that is modified by a particular airplane manufacturer to synchronize with the specifications of a particular aircraft. Each airplane manufacturer has their own proprietary technology that is incorporated into the LRU. Within the fleet of a particular airplane manufacturer there may be different technology within each LRU.

Aircraft use electronic systems to control the myriad of systems that are used to operate an aircraft. Aircraft manufacturers use LRUs that can be changed quickly if needed; this ability to change the LRU quickly with a replacement enables the aircraft to operate more efficiently. A designated area in every aircraft houses all or most of the LRUs; the is commonly referred to as the electronics bay. The LRUs in the electronic bay are typically in close proximity to each other in order to maximize space on the aircraft. Modern advances in aircraft design may alter the concept of the electronics bay but will not eliminate the testing requirement.

Aircraft systems include the operation of the landing gear, avionics, and navigation systems to name a few examples that are found in every aircraft regardless of the manufacturer of the airplane. Each of these systems must be operational to operate the aircraft safely. Each of these systems may be controlled by a LRU to perform key operations. There may also be numerous identical LRUs for a single system.

The LRUs are tested according to the rules and regulations that govern the operation of aircraft by governmental authorities or if there is a malfunction or error signal. In the prior art the technician who was responsible for this testing would be required to remove the LRU to access the back of the equipment rack, which is in close proximity to the inner shell of the aircraft. This was a very labor-intensive operation and often the technician would be required to remove the LRU as well as adjacent LRUs to enable the technician to connect testing equipment to testing probes where the back of the LRU is normally connected. This activity may cause damage to the wiring contacts inside the aircraft-side connector that normally mates with the LRU. The current device not only eliminates the possibility of damage to the aircraft-side connector contacts by minimizing any human contact with the testing probes, but also avoids costs for Return to Service testing requirements for those adjacent LRUs previously removed to facilitate maintenance. The wiring for the aircraft connects to back surface contact points of the LRU. During the troubleshooting for a particular problem, the technician may need to test the system at the location of the LRU.

The front testing ports of this device would connect to the back of the tray mount hosting the aircraft connector that normally mates with the LRU. A wire harness in the center of the LRU ensures that the wiring of the testing device remains intact. A handle is provided for the convenience of the technician.

### BRIEF DESCRIPTION OF THE DRAWINGS

FIG. 1 is an isometric or prospective view of the fragmented portion of the airplane along with the testing device.

FIG. 2 is a front view of the electronics bay.

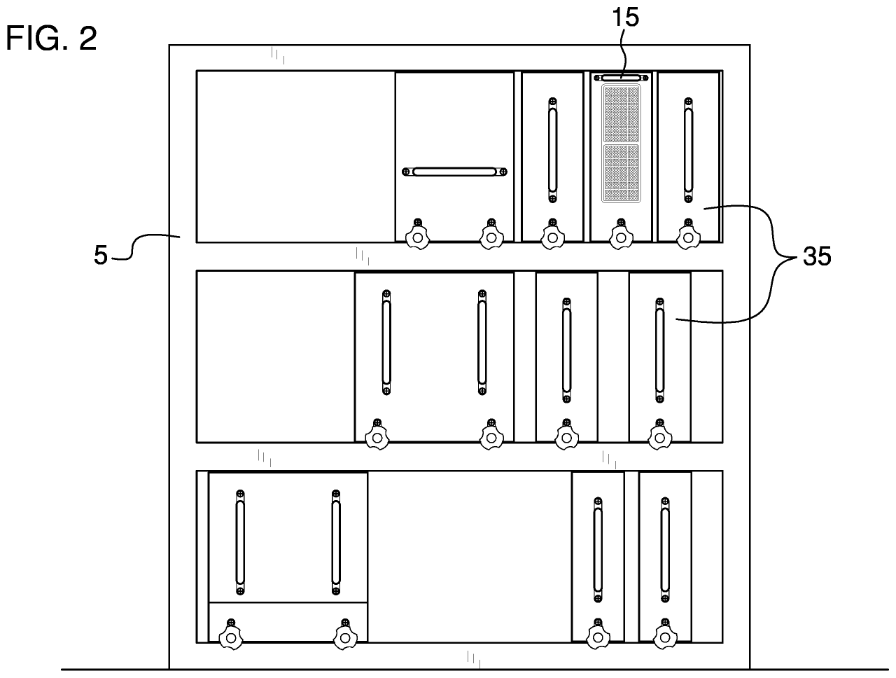

FIG. 3 is a side view of the testing device.

FIG. 4 is a back view of the testing device.

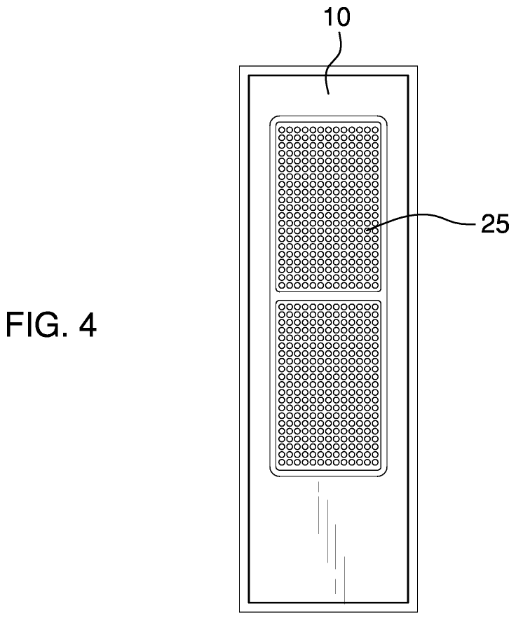

### NUMBERING DESCRIPTION

5—Electronics bay

10—Testing Device

15—Handle

20—Plurality of testing ports

25—Back connector

30—Wire harness

35—Control unit

### DETAILED DESCRIPTION OF THE EMBODIMENTS

In any airplane, there is a section, which is commonly referred to as the electronics bay 5, that houses many line replacement units (LRUs). A LRU, which is a structure with defined walls, a defined top surface, a defined bottom surface and defined front and back surfaces, is a piece of equipment that is purchased and then modified by the airplane manufacturer according to the specifications of a particular airplane. The LRUs control their system operations and integrate timing functions with the other systems through their respective controllers. The LRU houses electronics that control various systems on the airplane. The back panel of the LRU will be integrated with and attach to the wiring of the aircraft during operation of the aircraft. The LRUs are housed in an area of the airplane that is commonly referred to as the electronics bay 5.

The LRUs, which house the electronics for each system, control everything from the landing gear system to the avionics system to the navigation system to name a few examples. For purposes of this application the landing gear control unit (LGCU) which is a LRU that controls the landing gear will be discussed. Within the LGCU is housed electronics that control the operation of the landing gear. The testing device that is discussed in this application will specifically test for issues related to the LGCU. Although the LGCU is discussed in this application, the concept can also be applied to other LRUs that are found in an aircraft.

During normal operation of the aircraft there will be times when troubleshooting of the LGCU must occur. The technician may trace the problem back to the LGCU, which is in the electronics bay 5. Because the space is the electronics bay is limited and the spacing between individual LRUs is minimal it may be difficult for the technician to remove an individual LRU without the need to remove adjacent LRUs. The inability to rapidly test the LGCU (in this example) and diagnose a problem decreases the reliability and serviceability of the aircraft. Additionally, if adjacent LRUs must be removed, the technician must ensure that the LRUs that have been removed are reinstalled properly. The process of reinstalling the LRU may require extensive and intrusive maintenance testing to ensure systems are ready for returning the aircraft to service. As mentioned previously, the current device eliminates the need for the additional intrusive and maintenance testing and the associated costs.

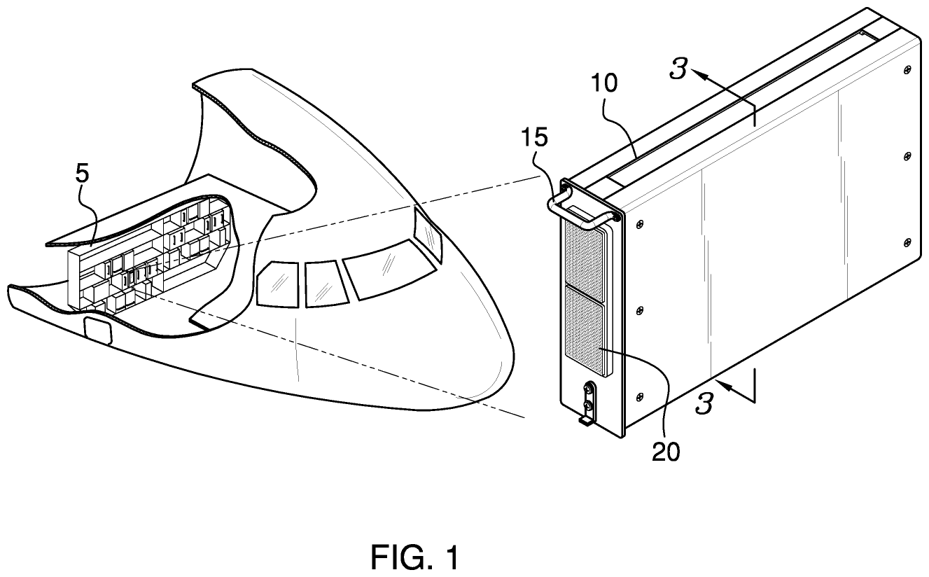

The testing device 10 will be a structure that is similar to the shape of a LRU with defined walls, defined top, defined bottom and defined front and back surfaces such as depicted in FIG. 1.

On the front of the testing device 10 will be a handle 15 for the convenience of the technician for manipulating the device while testing. To begin testing, the suspect LRU must be removed for operative maintenance and the technician temporarily installs the invention in its place. The technician slides the device into the tray mount and fastens the tray mount knurled knobs to the device receivers to secure the device to the tray that is fixed-mounted to the aircraft. A plurality of testing ports 20 will be positioned on the front of the testing device; a plurality of testing ports will be provided on the front connector 20. The technician will insert testing equipment into the plurality of testing ports on the front connector of the testing device to test the LGCU circuit wiring permanently installed on the aircraft.

A plurality of wires will extend from the testing ports on the front connector of the testing device to the back of the device which mates with the aircraft connector, mounted to the tray which secures the fixture in lieu of the LRU, coupling the device to the wiring of the aircraft. The device contains no electrical components but acts as a wiring jumper harness to bridge between the connectors on the airframe and the plurality of testing ports on the front of the device.

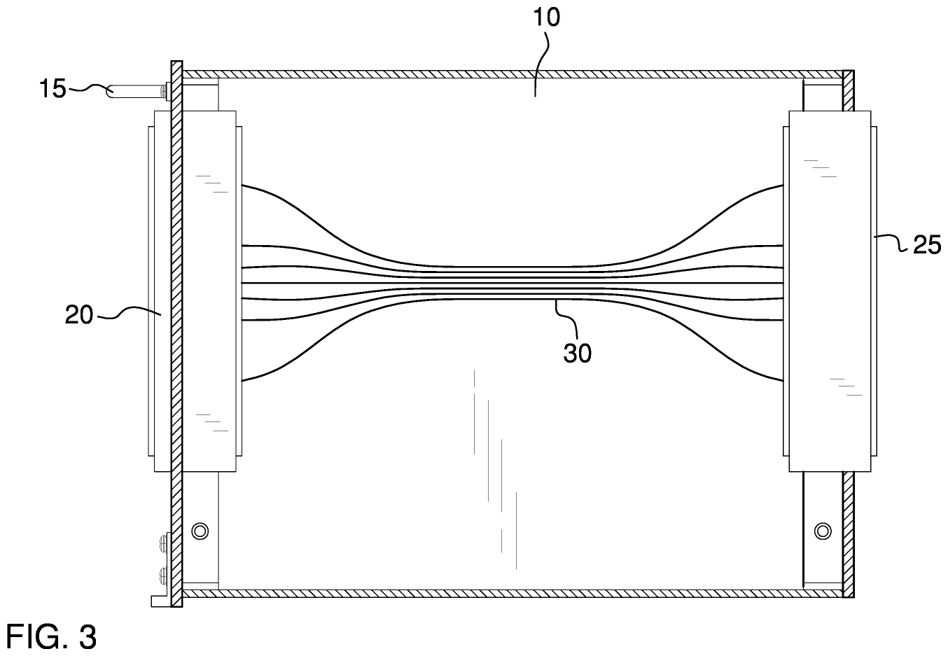

The plurality of testing ports 20 will connect to a series of wires which are in a wire harness 30 that will connect from the front connector 20 to the back connector 25 such as depicted in FIG. 3.

The back connector of the device 25 connects with the actual wiring of the airplane. During normal testing of the LGCU, a technician will first remove the LGCU and insert the testing device into the space that was occupied by the LGCU. The back connector will attach to the wiring of the aircraft. The technician would then insert the testing equipment into the front connector 20. This testing device eliminates the need for the technician to remove adjacent LRUs, which was sometimes required in the prior art.

While the embodiments of the invention have been disclosed, certain modifications may be made by those skilled in the art to modify the invention without departing from the spirit of the invention.

The testing of aircraft systems is required on a periodic basis according to Government regulations or when error messages occur. The application allows the technician to test the integrity of line replacement unit without the need to remove adjacent line replacement units. The technician will focus the scope of maintenance activities on the suspect system without the need to remove adjacent line replacement units.

The inventor claims:

1. An aircraft line replacement unit interface testing device that is comprised of:
a structure with a predetermined shape;
wherein the structure has defined side walls;
wherein the structure has a defined top surface;
wherein the structure has a defined bottom surface;
wherein the structure has a defined back surface;
wherein the structure has a defined front surface;
wherein the structure contains no electrical components;
wherein the interior of the structure contains a plurality of wires;
said plurality of wires extend from the back of the interior of the structure to the front of the interior of the structure;
a handle;
a receiver;
wherein a technician secures the device to the aircraft;
a front connector;
wherein a plurality of testing ports are provided on the front surface;
wherein a technician would insert testing equipment into the plurality of testing ports;
a back connector;
wherein a plurality of testing connection ports are provided on the back surface;
wherein the back connector would attach to the wiring of the aircraft;
wires;
a wire harness;
wherein the wire harness is provided in the interior of the aircraft line replacement testing device;
wherein the plurality of wires on the interior of the structure connect the testing ports on the back of the device to the testing ports on the front of the device;
wherein the wires connect the testing ports on the front connector to the testing connection of the back connector.

2. A method to use an aircraft line replacement unit interface testing device which is comprised of the following steps:
a. a technician removes a line replacement unit;
b. the technician removes the suspect line replacement unit under test;
c. the technician inserts the testing device into the space that was occupied by the line replacement unit;
d. the technician temporarily installs the test device by sliding the testing device into the LRU tray mount where the device back connector mates with and attaches to the wiring of the aircraft;
e. the technician inserts the testing equipment into the plurality of testing ports on the front of the aircraft line replacement unit testing device.
